(19) United States
(12) Patent Application Publication
(10) Pub. No.: US 2001/0012670 A1
(43) Pub. Date: Aug. 9, 2001

(54) SEMICONDUCTOR DEVICE AND METHOD MANUFACTURING SAME

(76) Inventors: AKIRA MINEJI, TOKYO (JP); SEIICHI SHISHIGUCHI, TOKYO (JP); SHUICHI SAITO, TOKYO (JP)

Correspondence Address: NORMAN P SOLOWAY, HAYES SOLOWAY HENNESSEY, GROSSMAN & HAGE, 175 CANAL STREET, MANCHESTER, NH, 03101

(21) Appl. No.: 09/196,415

(22) Filed: Nov. 19, 1998

(30) Foreign Application Priority Data
Nov. 20, 1997 (JP) 319755/1997

(51) Int. Cl. H01L 21/336; H01L 21/8234

(52) U.S. Cl. 438/305

(57) ABSTRACT

A semiconductor device is manufactured by a step of forming a gate electrode on a semiconductor substrate with a gate insulation film therebetween, and using this gate electrode as a mask to implant ions to achieve a high-dose doping of impurities, thereby forming a source/drain region, using an accelerating potential for ion implantation that is lower to a value at which implantation damage is not done to the gate insulation film.

### BACKGROUND OF THE INVENTION

1. Field of the Invention

The present invention relates to a semiconductor device manufacturing method and more particularly to a method of manufacturing a CMOS LSI device with a high level of integration and having a MOS structure with a thin gate electrode and shallow junction, and yet more specifically to a simplified method for manufacturing a high-performance logic or memory semiconductor device in which variations in threshold value are inhibited.

2. Background of the Invention

With a shrinking of the feature sizes in MOSFETs, in order to inhibit the short-channel effect and achieve a high driving capability, investigation has been done into making the region of a source/drain (S/D) diffusion layer near a gate electrode shallow and other regions deep, in what is called a double-drain structure.

The shallow region in proximity to the gate electrode is known as the extension region, in which by using a shallow but high concentration of impurities, it is possible to inhibit the short-channel effect, without causing a reduction in the driving capability.

In the part of the S/D diffusion region other than the extension region, a deep diffusion layer is formed so as to prevent an increase in layer resistance and an increase in leakage current in a silicide process step or wire forming process step.

This deep diffusion layer is formed by first forming the above-noted extension region, and then providing a gate side wall, after which ion implantation is done once again.

When forming the above-noted extension region, a spacer (side wall) is actually formed by, for example, oxidation of the side wall of a gate polysilicon electrode.

This is done in order to prevent a shortening of the channel length because of diffusion of the implanted impurity during activation in both the depth and lateral directions during activation, by adjusting the width of the side wall so as to adjust the amount of ion implantation.

Because it is usually necessary to perform ion implantation with a high concentration into the extension region, if the gate is exposed, impurity and ion implantation damage will introduced in the part noted as implantation damage 8 in FIG. 7(a).

This can cause an increase in leakage current because of a drop in the gate oxide film withstand voltage when the semiconductor device is driven, thereby leading to a lowering of reliability.

As described above, using the ion implantation technology of the past, there was a need to provide a side wall on a side surface of the electrode when performing ion implantation into an extension region.

One method which can be envisioned to avoid the introduction of impurities and ion implantation damage into the gate oxide film, in the example shown in FIG. 7(b), is that of removing the damaged region that is introduced by ion implantation into the gate oxide film, thereby removing the cause of deterioration of the gate oxide film characteristics (M. Takase et al, Ex. Abstr. of SSDM (1996), pp. 410-412). Such removed portion is indicated by numerical number 9 in FIG. 7(b).

With this method, however, even though it might be possible, by a process step of forming an interlayer film at the removed part of the oxide film, to introduce a poor-quality insulation or contaminating material, it is thought that there is no possibility of burying a film as good or better in quality than the gate oxide film.

Additionally, this unavoidably leads to an increase in the number of process steps, and presents problems with regard to process stability as well.

As discussed above, with the prior art it was necessary to use a high dose of ion implantation to form an extension region and, from the standpoint of controllability and a reduction in the number of process steps, it is advantage to perform ion implantation in the condition in which the gate electrode does not have a side wall.

However, it is necessary to inhibit channel shortening caused by lateral diffusion of the impurity and, because of the extremely thin gate oxide film that is required as the element size becomes smaller, if impurity ions and ion implantation damage is allowed to occur in the gate oxide film, this will directly influence electrical characteristics, leading to the problems of reduced withstand voltage and reliability.

In achieving faster LSI devices with reduced power consumption, with a shrinking of the size of MOS transistors, there is a need to form a MOSFET that has a thin diffusion layer, and to inhibit the channel shortening effect.

Accordingly, an object of the present invention is to provide a method form manufacturing a semiconductor device which achieves the formation of a thin source/drain diffusion region, and also the inhibition of the introduction of impurities and ion implantation damage into the gate oxide film, thereby improving the electrical characteristics of the element, while simplifying and stabilizing the manufacturing process.

### SUMMARY OF THE INVENTION

To achieve the above-noted object, the a method for manufacturing a semiconductor device according to the present invention has a step of forming a gate electrode on a semiconductor substrate with an intervening gate insulation film therebetween, and a step which a source/drain region is formed by ion implantation of an impurity using the above-noted gate electrode as a mask, this ion implantation being performed with an accelerating potential lowered to a value at which does not cause implantation damage to the above-noted gate insulation film.

In the above-noted semiconductor manufacturing method according to the present invention, in the case of implanting the dopant boron, the dose amount is set to 2×10¹⁴/cm² or higher, and the ion implantation accelerating potential is set to 1 keV or lower.

In the above-noted semiconductor manufacturing method according to the present invention, in the case of implanting the dopant BF2, the dose amount is set to 2×10¹⁴/cm² or higher, and the ion implantation accelerating potential is set to 3 keV or lower.

In the above-noted semiconductor manufacturing method according to the present invention, in the case of implanting the dopant arsenic, the dose amount is set to 5×10¹³/cm² or higher, and the ion implantation accelerating potential is set to 5 keV or lower.

In the above-noted semiconductor manufacturing method according to the present invention, in the case of implanting the dopant phosphorus, the dose amount is set to 5×10¹⁴/cm² or higher, and the ion implantation accelerating potential is set to 5 keV or lower.

In general, ion implantation into the source/drain region using the gate electrode as a mask is performed at a dose amount of from 5×10¹³/cm² to 3×10¹⁵/cm².

With the ions that are normally implanted as dopants into a silicon substrate, a large amount of ion implantation damage occurs.

In the ion implantation process step, as shown in FIG. 8 (and noted in S. M. Sze, Physics of Semiconductor Devices), ions in a beam that is accelerated in an ion implantation machine exhibit a finite statistical width in both the direction of travel and laterally (the width in the direction of travel being (RP and the lateral width being (RT), these widths increasing with an increase in the accelerating potential.

Therefore, the higher the accelerating potential is, the larger the number of ions will be that are diffused laterally, and the larger will be the amount of impurity that is introduced into the side wall part of the gate oxide film that is in contact with the silicon substrate.

Because shrinking semiconductor element size has brought with it extremely thin gate oxide films, the dopant and implantation damage introduced into this gate oxide film affects the electrical characteristics.

In ion implantation according to the present invention, by setting the accelerating potential to a value at which there is no implantation damage to the gate insulation film, a deterioration of the gate oxide film characteristics is prevented.

### DESCRIPTION OF THE DRAWINGS

FIG. 1 is a process cross-sectional view that shows the first embodiment of the present invention.

FIG. 2 is a graph that shows the operating characteristics of the present invention.

FIG. 3 is a graph that shows the operating characteristics of the present invention.

FIG. 4 is a graph that shows the operating characteristics of the present invention.

FIG. 5 is a process cross-sectional view that shows the second embodiment of the present invention.

FIG. 6 is a process cross-sectional view that shows the third embodiment of the present invention.

FIG. 7 is a cross-sectional view that shows the prior art.

FIG. 8 is a drawing that shows the nature of ion implantation, by way of illustration of the action of the present invention.

FIG. 9 is a cross-sectional view of one embodiment of a semiconductor device produced by the present invention.

### DESCRIPTION OF THE PREFERRED EMBODIMENTS

Preferred embodiments of the present invention are described below in detail, with reference being made to relevant accompanying drawings. It should be noted that, although the embodiments are described below with regard to the manufacture of a MOSFET, the present invention is not restricted in application to a MOSFET, and be applied to the manufacturing of a wide range of semiconductor devices in which there is a step of forming an electrode on a semiconductor substrate with an insulation film therebetween, and then using the electrode as a mask for ion implantation to achieve a high dose of doping, thereby forming a doped region, such as in the manufacturing of a non-volatile semiconductor memory as typified by a flash memory device.

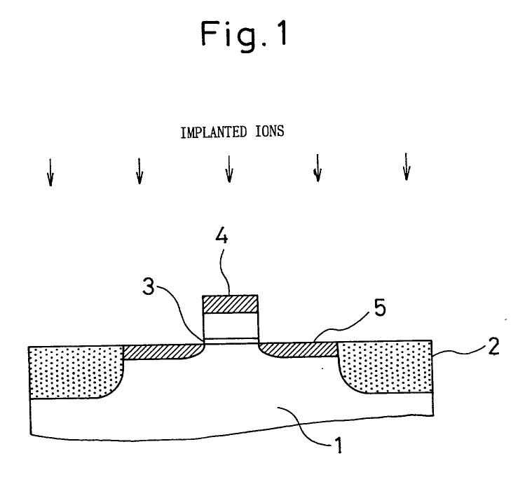

The first embodiment of the present invention is described below, with reference being made to the process cross-sectional view presented in FIG. 1.

First, after selectively forming a field oxide film 2 onto a silicon substrate 1, a gate oxide film 3 and polysilicon are deposited, and patterning is used to perform anisotropic etching, thereby forming a gate electrode 4, which has a perpendicular shape with respect to the silicon substrate 1.

Next, so as to avoid implantation damage to the gate oxide film, ion implantation is performed perpendicularly with respect to the surface of the silicon substrate 1 and at a low accelerating potential.

In the case, for example, in which a p-type MOSFET is to be fabricated, by ion implanting boron, the accelerating potential is set to 1 keV or lower, and the implantation dose amount is set to 2×10₁₄/cm².

In the case of implanting BF2 ions, the accelerating potential is set to 3 keV or lower, and the implantation dose amount is set to 1×10¹⁵/cm².

In the case of implanting arsenic ions, the accelerating potential is set to 5 keV or lower, and the implantation dose amount is set to 5×10¹⁴/cm².

In the case of implanting phosphorus ions, the accelerating potential is set to 5 keV or lower, and the implantation dose amount is set to 5×10¹⁴/cm².

The dose amount can be set as required, but should be set to no lower than 2×10¹⁴/cm² for the cases of boron and BF2 ions and no lower than 5×10¹³/cm² for the cases of arsenic and phosphorus.

Then, a side wall 8 is formed on the gate electrode 4 and ion implantation is performed so as to form a deep diffusion layer 9, 10, and then an activation processing is done, thereby completing the lower layer of a double-drain MOSFET, as shown in FIG. 9.

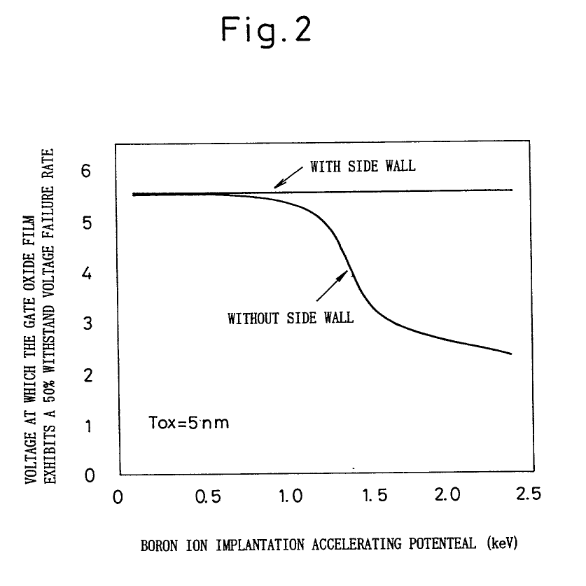

The characteristics of the semiconductor element shown in FIG. 1 are described as follows, with reference FIG. 2, which shows a comparison of the initial withstand voltage of the gate oxide film of a MOSFET according to this embodiment of the present invention with that of the prior art.

In this comparison, the gate oxide film thickness (TOX) is 5 nm.

For the case in which extension region ion implantation is performed with no gate side wall, the lower the boron implantation energy (acceleration) is made, the more inhibition there is of the deterioration from the initial withstand voltage, and at 1 keV or below, a withstand voltage is achieved that is equivalent to that achieved with a side wall.

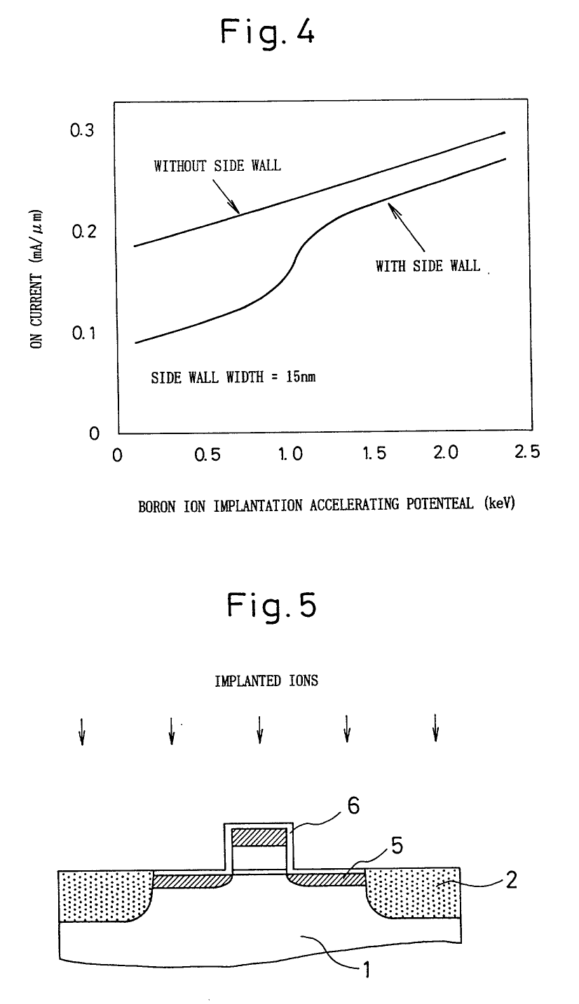

In the case in which a side wall is formed, as shown in FIG. 4, when the boron implantation energy is lowered to 1 keV or lower, there is a prominent deterioration of on current during operation.

This is because of the offset structure of the transistor, which means that dopant which is ion implanted with the side wall as a mask does not sufficiently exhibit lateral diffusion even with activation processing, so that the junction does not reach the edge of the gate electrode.

Therefore, when forming this type of shallow junction using a low acceleration potential for ion implantation, it is necessary as the accelerating potential is lowered to make the thickness of the side wall smaller to suit the lateral diffusion distance of the implanted dopant.

However, in forming such a thin side wall, because of the difficulty in controlling the wall thickness and maintaining process stability, it is more desirable to perform ion implantation without providing a side wall.

In the case of the other dopants, BF2, arsenic, and phosphorus, as well, the same type of characteristics as shown in FIG. 2 are obtained.

To obtain the same type of withstand voltage as the case in which a side wall is provided, for BF2 ion implantation the accelerating potential is set to no greater than 3 keV, for arsenic ion implantation the accelerating potential is set to no greater than 5 keV, and for phosphor ion implantation the accelerating potential is set to no greater than 5 keV.

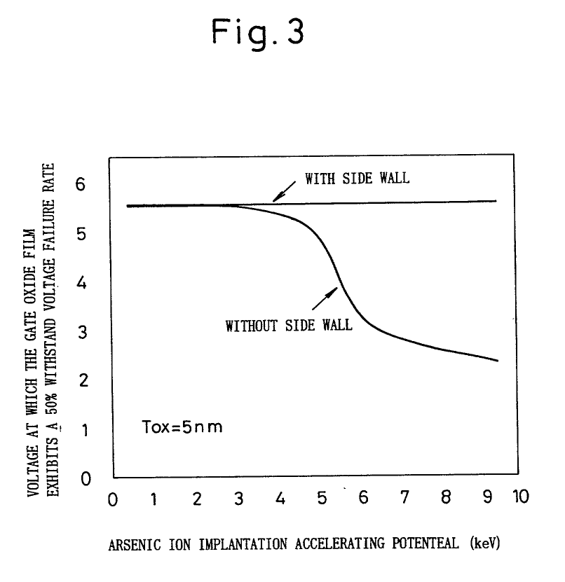

FIG. 3 shows a comparison of the initial withstand voltage of a gate oxide film for the case of implanting arsenic ions as a dopant in an n-type MOSFET, with the case of the prior art. In this comparison, the gate oxide thickness (Tox) is 5 nm.

The second embodiment of the present invention will now be described, with reference being made to FIG. 5.

After the process steps described with respect to the first embodiment, a gate electrode is formed on the surface of the silicon substrate. Next, using either thermal oxidation or CVD (chemical vapor deposition), an oxide film 6 having a thickness of no greater than 5 nm is formed on the surface of the silicon substrate so as to cover the gate electrode.

Then, extension region ions (boron) are implanted with an accelerating potential of 1 keV or lower.

In this configuration, because the gate oxide film is protected by this oxide film, there is an advantage in terms of a broadened process window with respect to ion implantation acceleration.

By making the thickness of the oxide film no greater than 5 nm, the range of dispersion of ions when they are implanted with a low acceleration is limited to within the oxide film, thereby eliminating the need for concern that they might be introduced into the substrate itself.

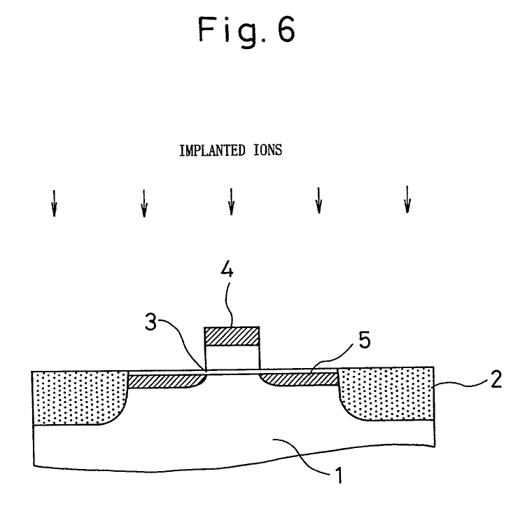

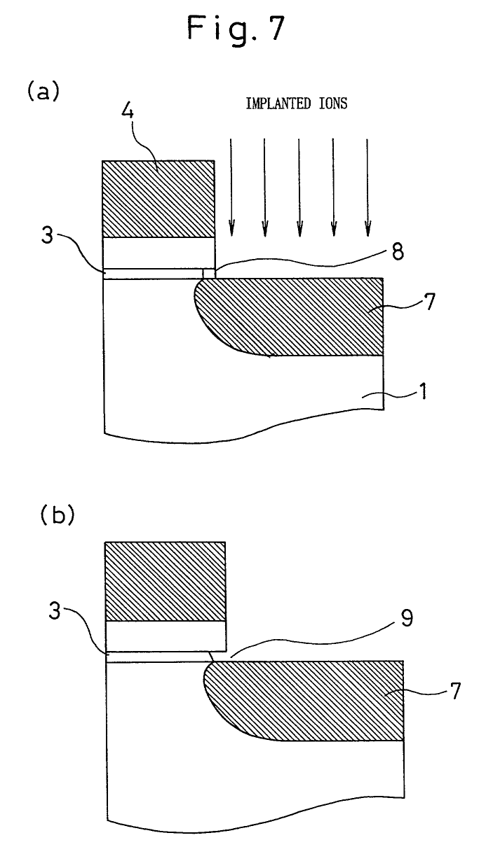

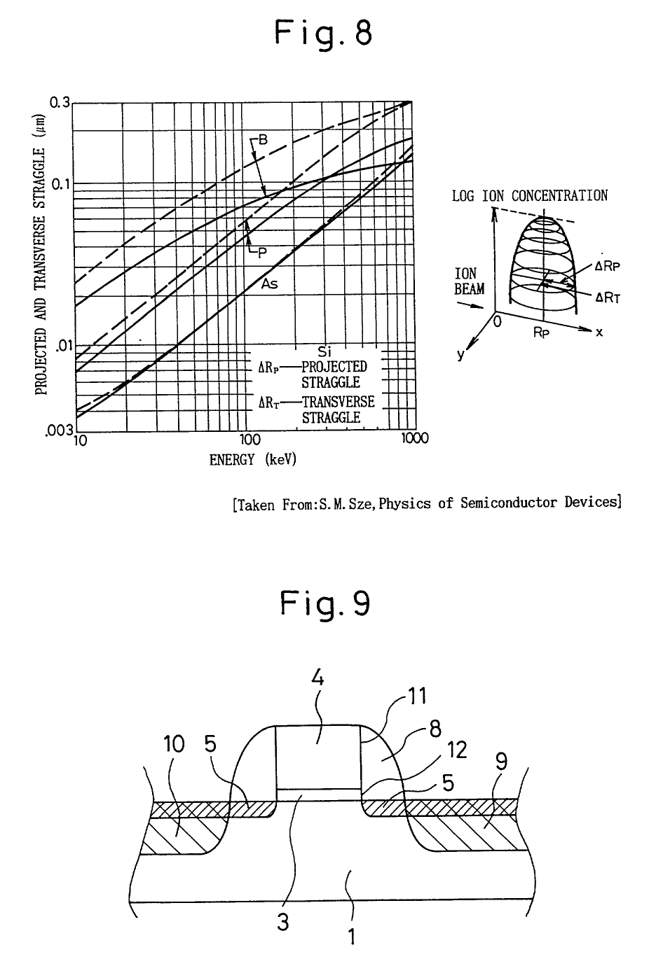

The third embodiment of the present invention is shown in FIG. 6.

In this embodiment, after selectively forming a field oxide film 2 on the surface of the silicon substrate 1, a gate oxide film 3 and polysilicon are deposited, and patterning is done to perform anisotropic etching, thereby forming a gate polysilicon electrode 4 having a shape that is perpendicular with respect to the surface of the silicon substrate.

At this time, the gate oxide film on the silicon substrate is made thin, without performing etching. By means of this gate oxide film, it is possible to prevent heavy metal contamination when ion implantation is done.

If the gate oxide film is made no thicker than 5 nm, the gate oxide film thickness after removal of the polysilicon will be no greater than this thickness of 5 nm.

Next, ion implantation at a low acceleration is performed as in the case described with regard to the first embodiment, thereby forming the extension region.

One embodiment of a feature of the semiconductor device formed by the method of the present invention as mentioned above, will be explained with reference to FIG. 9.

As shown in FIG. 9, a semiconductor device of the present invention comprises a substrate 1, a gate electrode 4 formed on a surface of the substrate 1 with interposing a gate insulation film 3 therebetween, side walls 8 provided on both side surface of the gate electrode 4 and the surface of the substrate 1, source/drain regions 9, 10 containing impurities dosed therein formed on a part of the surface of the substrate 1 which is not covered with the side wall 8 and shallow extension regions 5 containing impurities dosed therein, dosed amount of the impurities thereof being greater than that of the source/drain regions 9, 10 and formed on a part of the substrate 1 which is covered with the side wall 8, and further wherein a side surface 11 of the electrode 4 and an end surface 12 of the gate insulation film 3 forming a uniform flat surface.

Further, in the semiconductor device of the present invention, the end surface 12 of the gate insulation film 3 is suffered from no damage caused by ion implanting operation.

As described in detail above, because the present invention forms a shallow diffusion region (extension region) with good control and without an accompanying deterioration of the gate oxide film characteristics, it facilitates the fabrication of a high-speed, high-density MOSFET device.

What is claimed is:

1. A method of manufacturing a semiconductor device, comprising steps of forming a gate electrode on a semiconductor substrate with an intervening gate insulation film therebetween, and forming a source/drain region by ion implantation of impurities using said gate electrode as a mask, and wherein said ion implantation being performed with an accelerating potential lowered to a value at which does not cause implantation damage to said gate insulation film.

2. A method of manufacturing a semiconductor device according to claim 1, wherein at least a part of said source/drain region forming shallow diffusing regions.

3. A method of manufacturing a semiconductor device according to claim 2, wherein shallow diffusing regions forming extension regions of said source/drain region.

4. A method of manufacturing a semiconductor device according to claim 1, wherein when said shallow diffusing region is formed, said gate electrode is provided with no side wall on side surfaces thereof.

5. A method of manufacturing a semiconductor device according to claim 1, wherein for a case of implanting boron ions by said ion implantation step, the dose amount is set at 2×10¹⁴ cm² or higher, and the ion implantation accelerating potential is set to 1 kev or lower.

6. A method of manufacturing a semiconductor device according to claim 1, wherein for a case of implanting BF₂ ions by said ion implantation step, the dose amount is set at 2×10¹⁴ cm² or higher, and the ion implantation accelerating potential is set to 3 keV or lower.

7. A method of manufacturing a semiconductor device according to claim 1, wherein for a case of implanting arsenic ions by said ion implantation step, the dose amount is set at 5×10¹³ cm² or higher, and the ion implantation accelerating potential is set to 5 keV or lower.

8. A method of manufacturing a semiconductor device according to claim 1, wherein for a case of implanting phosphorus ions by said ion implantation step, the dose amount is set at 5×10¹³ cm² or higher, and the ion implantation accelerating potential is set to 5 keV or lower.

9. A semiconductor device which comprises a substrate, an electrode formed on a surface of said substrate with interposing a gate insulation film therebetween, side walls provided on both side surface of said electrode and said surface of said substrate, source/drain regions containing impurities dosed therein formed on a part of said surface of said substrate which is not covered with said side wall and shallow extension regions containing impurities dosed therein, dosed amount of said impurities thereof being greater than that of said source/drain regions and formed on a part of said substrate which is covered with said side wall, and further wherein a side surface of said electrode and an end surface of said gate insulation film forming a uniform flat surface.

10. A semiconductor device according to claim 9, wherein said end surface of said gate insulation film being suffered from no damage caused by ion implanting operation.
